(19) United States
(12) Patent Application Publication
(10) Pub. No.: US 2026/0130090 A1
(43) Pub. Date: May 7, 2026

(54) DISPLAY DEVICE, ELECTRONIC DEVICE, AND METHOD FOR FABRICATING THE DISPLAY DEVICE

(71) Applicant: Samsung Display Co., LTD., Yongin-si (KR)

(72) Inventors: Hyun Min CHO, Yongin-si (KR); Tae Sang PARK, Yongin-si (KR); Dong Gyu JIN, Yongin-si (KR); Yu Gwang JEONG, Yongin-si (KR)

(21) Appl. No.: 19/279,382

(22) Filed: Jul. 24, 2025

(30) Foreign Application Priority Data
Nov. 4, 2024 (KR) 10-2024-0154703
Jan. 21, 2025 (KR) 10-2025-0008596

(51) Int. Cl. H10K 59/80; H10H 29/01; H10H 29/80; H10K 71/60; H10K 102/00; H10K 102/10

(52) U.S. Cl. CPC H10K 59/80517; H10H 29/032; H10H 29/8323; H10K 71/60; H10K 2102/102; H10K 2102/103; H10K 2102/351

(57) ABSTRACT

There is provided a display device. The display device includes a substrate including a light emitting area; an anode electrode positioned on the light emitting area of the substrate and including silver; and an element insulating layer covering an edge of the anode electrode and defining a light emitting opening, wherein the anode electrode includes: a first layer positioned on the substrate; a second layer positioned on the first layer; and a third layer positioned on the second layer and including a protruding portion that protrudes further compared to a side surface of the second layer, and a width of the protruding portion of the third layer is 0.1 micrometers or less.

This application claims priority to Korean Patent Application No. 10-2024-0154703, filed on Nov. 4, 2024, and Korean Patent Application No. 10-2025-0008596, filed on Jan. 21, 2025, and all the benefits accruing therefrom under 35 U.S.C. § 119, the contents of which in their entirety are herein incorporated by reference.

### BACKGROUND

### 1. Field

The present disclosure relates to a display device, an electronic device using the display device, and a method for fabricating the display device.

### 2. Description of the Related Art

As an information society develops, the demand for display devices of various forms for displaying an image is increasing. For example, display devices have been applied to various electronic devices such as smartphones, digital cameras, laptop computers, navigation devices, and smart televisions. Such display devices may include a flat panel display device such as a liquid crystal display device, a field emission display device, or an organic light emitting display device. Among the flat panel display devices, the light emitting display device may include a light emitting element in which each of the pixels of a display panel may emit light by itself, thereby displaying an image without a backlight unit providing the light to the display panel.

### SUMMARY

Aspects of the present disclosure provide a method for patterning an anode electrode applicable to a high-resolution display device and an electronic device using the high-resolution display device.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

Details of other embodiments are included in the detailed description and drawings.

In an embodiment of the disclosure, a display device includes a substrate including a light emitting area; an anode electrode positioned on the light emitting area of the substrate and including silver; and an element insulating layer covering an edge of the anode electrode and defining a light emitting opening, wherein the anode electrode includes: a first layer positioned on the substrate; a second layer positioned on the first layer; and a third layer positioned on the second layer and including a protruding portion that protrudes further compared to a side surface of the second layer, and a width of the protruding portion of the third layer is 0.1 micrometers or less.

In an embodiment, the first layer may include an upper surface, the upper surface of the first layer includes a first portion that is not in contact with the second layer and a second portion that is in contact with the second layer, and a width of the first portion is 0.1 micrometers or less.

In an embodiment, a thickness of the second layer may be greater than a thickness of the first layer and a thickness of the third layer.

In an embodiment, the first layer and the third layer may each include a transparent conductive material.

In an embodiment, the light emitting area may include a first light emitting area and a second light emitting area adjacent to each other, The display device further includes a first resonant auxiliary layer overlapping the first light emitting area and positioned between the first layer of the anode electrode and the substrate; and a second resonant auxiliary layer overlapping the second light emitting area and spaced apart from the first resonant auxiliary layer, and a thickness of the first resonant auxiliary layer and a thickness of the second resonant auxiliary layer may be different from each other.

In an embodiment, the display device may include the anode electrode in plurality, a first anode electrode of the plurality of anode electrodes may be positioned on the first resonant auxiliary layer, a second anode electrode of the plurality of anode electrodes may be positioned on the second resonant auxiliary layer, and the first anode electrode and the second anode electrode may be positioned at different heights.

In an embodiment, the display device may include the anode electrode in plurality, a first anode electrode of the plurality of anode electrodes may overlap the first light emitting area, a second anode electrode of the plurality of anode electrodes may overlap the second light emitting area, and a gap between the second layer of the first anode electrode overlapping the first light emitting area and a gap between the second layer of the second anode electrode overlapping the second light emitting area may each be 1.86 micrometers or less.

In an embodiment, the display device may further include a residual pattern positioned in contact with the third layer of the anode electrode and positioned such that the residual pattern surrounds the light emitting opening, wherein the residual pattern overlaps the protruding portion included in the third layer of the anode electrode.

In an embodiment of the disclosure, a method for fabricating a display device, the method includes forming a first layer, a second layer, and a third layer of an anode electrode on an entire surface, removing a portion of the third layer by performing a dry etching process; performing plasma treatment on a portion of the second layer; performing a cleaning process after the plasma treatment; and removing a portion of the first layer by performing a dry etching process.

In an embodiment, the first layer and the third layer each include a transparent conductive material, and the second layer may include silver.

In an embodiment, the plasma treatment may be performed using a gas including fluorine, and may use a bias power of 0 W among process parameter values of the plasma treatment.

In an embodiment, the plasma treatment further includes oxygen gas, and a portion of the second layer may include silver fluoride.

In an embodiment, performing the cleaning process may include dissolving the silver fluoride using at least one of organic stripper or deionized water.

In an embodiment, the third layer may include a protruding portion that protrudes further compared to a side surface of the second layer, and a width of the protruding portion may be 0.1 micrometers or less.

In an embodiment, a side surface of the first layer, a side surface of the second layer, and a side surface of the third layer may be positioned on the same line.

In an embodiment of the disclosure, an electronic device includes at least one display device including a substrate including a light emitting area; and a display module, a processor, a memory, and a power module, wherein at least one of the display module, the processor, the memory, or the power module is connected to the display device, wherein the at least one display device includes: an anode electrode positioned on the light emitting area of the substrate and including silver; and an element insulating layer covering an edge of the anode electrode and defining a light emitting opening, the anode electrode includes: a first layer positioned on the substrate; a second layer positioned on the first layer; and a third layer positioned on the second layer and including a protruding portion that protrudes further compared to a side surface of the second layer, and a width of the protruding portion of the third layer is 0.1 micrometers or less.

According to the display device and the method for fabricating the display device according to an embodiment, the anode electrode may be patterned by performing a plasma treatment process and a cleaning process. The display device according to an embodiment may form a gap between adjacent light emitting elements within an appropriate range applicable to high-resolution products by minimizing an overhang structure of the anode electrode.

It should be noted that the effects of the present disclosure are not limited to those described herein, and other effects not mentioned will be clearly understood by those skilled in the art from the description below.

### BRIEF DESCRIPTION OF THE DRAWINGS

The above and other aspects and features of the present disclosure will become more apparent by describing in detail embodiments thereof with reference to the attached drawings, in which:

FIG. 1 is an exploded perspective view illustrating a display device according to an embodiment;

FIG. 2 is a plan view illustrating an example of a display panel illustrated in FIG. 1;

FIG. 3 is an equivalent circuit diagram of a first pixel according to an embodiment;

FIG. 4 is a plan view illustrating an arrangement of a plurality of pixels disposed in a display area in FIG. 2;

FIG. 5 is a cross-sectional view of a display device according to an embodiment taken along line X1-X1′ of FIG. 4;

FIG. 6 is an enlarged cross-sectional view of a display element layer overlapping a first light emitting area and a second light emitting area in FIG. 5;

FIG. 7 is an enlarged cross-sectional view of an anode electrode of FIG. 5;

FIG. 8 is an enlarged cross-sectional view of an anode electrode of FIG. 5 according to another embodiment;

FIG. 9 is a flowchart illustrating a method for fabricating an anode electrode according to an embodiment;

FIGS. 10 to 12 are cross-sectional views illustrating step S100 of FIG. 9;

FIGS. 13 and 15 are cross-sectional views illustrating a plasma treatment process during step S200 of FIG. 9;

FIG. 14 is a cross-sectional view illustrating a mechanism by which silver fluoride is formed;

FIGS. 16 to 18 are cross-sectional views illustrating a cleaning process during step S200 of FIG. 9;

FIGS. 19 and 20 are cross-sectional views illustrating step S300 of FIG. 9;

FIG. 21 is a block diagram of an electronic display device according to an embodiment; and

FIG. 22 illustrates schematic diagrams of electronic devices according to various embodiments.

### DETAILED DESCRIPTION

The invention now will be described more fully hereinafter with reference to the accompanying drawings, in which various embodiments are illustrated. Aspects supported by the present disclosure may, however, be embodied in many different forms, and should not be construed as limited to the embodiments set forth herein. Rather, the example embodiments are provided such that this disclosure will be thorough and complete, and will fully convey the scope of example aspects of the present disclosure to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third,” and the like may be used herein to describe various elements, components, regions, layers and/or sections, these elements, components, regions, layers and/or sections should not be limited by these terms. These terms are used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments and is not intended to be limiting. As used herein, the singular forms “a,” “an,” and “the” are intended to include the plural forms, including “at least one,” unless the content clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as, for example, “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” based on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings.

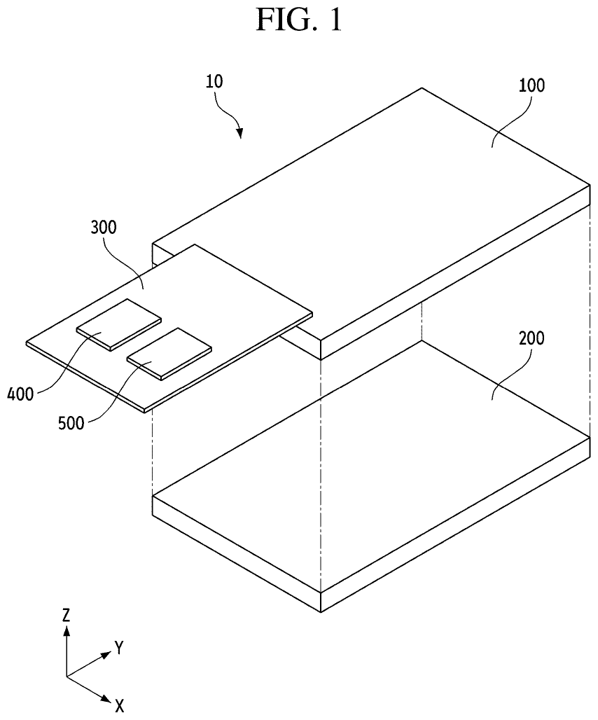

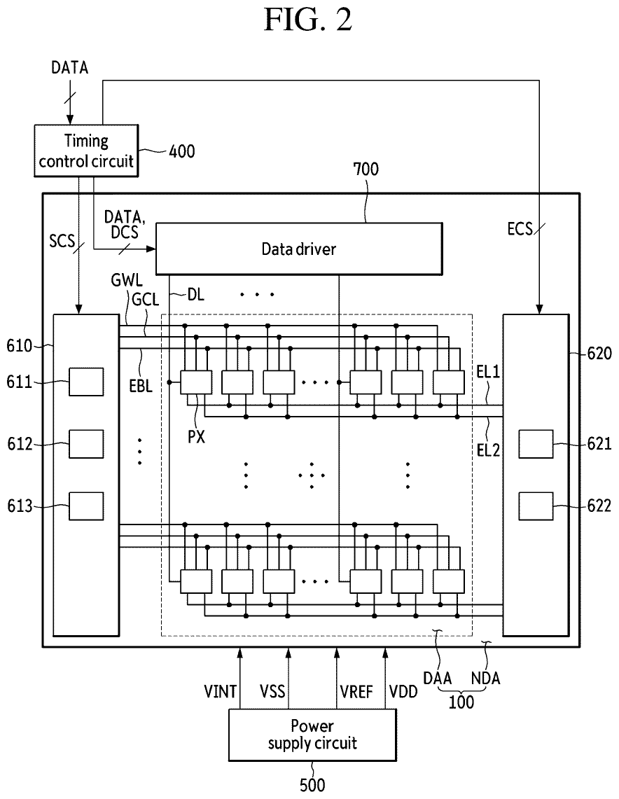

FIG. 1 is an exploded perspective view illustrating a display device according to an embodiment. FIG. 2 is a block diagram illustrating the display device according to an embodiment.

Referring to FIGS. 1 and 2, a display device 10 according to an embodiment is a device that displays a moving image or a still image. The display device 10 according to an embodiment may be applied to portable electronic devices such as, for example, a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 according to an embodiment may be applied to a display unit of a television, a laptop computer, a monitor, a billboard, or the Internet of Things (IoT). Alternatively, the display device 10 according to an embodiment may be applied to a smart watch, a watch phone, and a head mounted display (HMD) for implementing virtual reality and augmented reality.

The display device 10 according to an embodiment includes a display panel 100, a heat dissipation layer 200, a circuit board 300, a timing control circuit 400, and a power supply circuit 500.

The display panel 100 may be formed in a planar shape similar to a quadrangle. For example, the display panel 100 may have a planar shape similar to a quadrangle having short sides in a first direction (X-axis direction) and long sides in a second direction (Y-axis direction) intersecting the first direction (X-axis direction). In the display panel 100, a corner where the short side in the first direction (X-axis direction) and the long side in the second direction (Y-axis direction) meet each other may be formed at a right angle or may be formed in a round shape having a predetermined curvature. The planar shape of the display panel 100 is not limited to the quadrangle, and may be formed similarly to other polygons, circles, or ovals. A planar shape of the display device 10 may follow the planar shape of the display panel 100, but embodiments of the present disclosure are not limited thereto.

As illustrated in FIG. 2, the display panel 100 includes a display area DAA displaying an image and a non-display area NDA that does not display an image.

A plurality of pixels PX, a plurality of scan lines SL, a plurality of emission control lines EL1 and EL2, and a plurality of data lines DL may be positioned in a portion overlapping the display area DAA.

The plurality of scan lines SL and the plurality of emission control lines EL1 and EL2 may extend in the first direction (X-axis direction) and may be positioned in the second direction (Y-axis direction). In some aspects, the plurality of data lines DL may extend in the second direction (Y-axis direction) and may be positioned in the first direction (X-axis direction). In an embodiment, the plurality of scan lines SL may include a plurality of write scan lines GWL, a plurality of control scan lines GCL, and a plurality of bias scan lines GBL. The plurality of emission control lines EL1 and EL2 may include a plurality of first emission control lines EL1 and a plurality of second emission control lines EL2.

The plurality of pixels PX may be arranged in a matrix form in the first direction (X-axis direction) and the second direction (Y-axis direction). Each pixel PX may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each pixel PX may receive a data voltage of the data line DL according to a write scan signal of the write scan line GWL, and may emit light from the light emitting element according to the data voltage.

A scan driver 610, a light emitting driver 620, and a data driver 700 may be positioned in a portion overlapping the non-display area NDA.

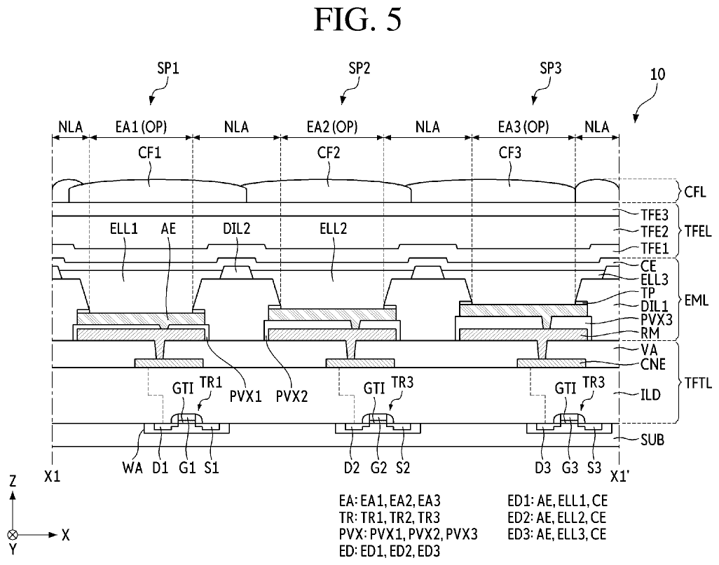

The scan driver 610 includes a plurality of scan transistors, and the light emitting driver 620 includes a plurality of light emitting transistors. The plurality of scan transistors and the plurality of light emitting transistors may be formed through a semiconductor process and may be formed on a semiconductor substrate (SUB in FIG. 5). For example, the plurality of scan transistors and the plurality of light emitting transistors may be formed of CMOS. It is illustrated in FIG. 2 that the scan driver 610 is disposed on the left side of the display area DAA and the light emitting driver 620 is disposed on the right side of the display area DAA, but embodiments of the present disclosure are not limited thereto. For example, the scan driver 610 and the light emitting driver 620 may be disposed on both the left and right sides of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The light emitting driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed through a semiconductor process and may be formed on a semiconductor substrate (SUB in FIG. 5). For example, the plurality of data transistors may be formed of CMOS.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this case, at least one of the plurality of pixels PX may be selected by the write scan signal of the scan driver 610, and the data voltages may be supplied to the selected pixel PX.

The heat dissipation layer 200 may overlap the display panel 100 in a third direction (Z-axis direction), which is a thickness direction of the display panel 100. The heat dissipation layer 200 may be positioned on one surface of the display panel 100, for example, a rear surface of the display panel 100. The heat dissipation layer 200 serves to dissipate heat generated from the display panel 100. The heat dissipation layer 200 may include a metal layer such as, for example, graphite, silver (Ag), copper (Cu), or aluminum (Al) having high thermal conductivity.

The circuit board 300 may be electrically connected to pads of the display panel 100 by using a conductive adhesive member such as, for example, an anisotropic conductive film. The circuit board 300 may be a flexible printed circuit board or flexible film formed of a flexible material. It is illustrated in FIG. 1 that the circuit board 300 is unfolded, but the circuit board 300 may be bent. In this case, one end of the circuit board 300 may be positioned on the rear surface of the display panel 100 and/or a rear surface of the heat dissipation layer 200. One end of the circuit board 300 may be an opposite end of the other end of the circuit board 300 connected to a pad portion of the display panel 100 by using a conductive adhesive member.

The timing control circuit 400 may receive digital video data and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the light emitting driver 620. The timing control circuit 400 may output the digital video data and the data timing control signal DCS to the data driver 700.

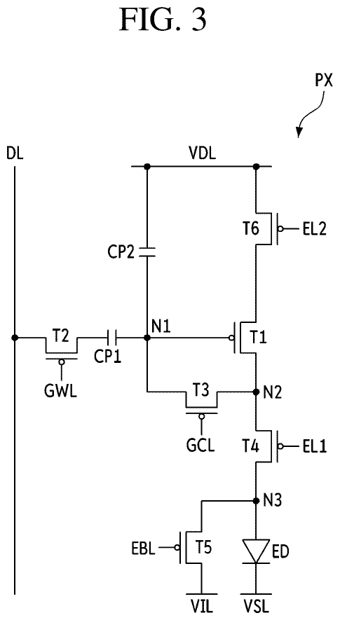

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply the generated driving voltages to the display panel 100. A description of the first driving voltage VSS, the second driving voltage VDD, and the third driving voltage VINT will be described later with reference to FIG. 3.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In some aspects, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be positioned in the non-display area NDA of the display panel 100, similarly to the scan driver 610, the light emitting driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process and may be formed on a semiconductor substrate (SUB in FIG. 5). For example, the plurality of timing transistors and the plurality of power transistors may be formed of CMOS.

FIG. 3 is an equivalent circuit diagram of a pixel according to an embodiment.

Referring to FIG. 3, the pixel PX may be connected to the write scan line GWL, the control scan line GCL, the bias scan line EBL, the first emission control line EL1, the second emission control line EL2, and the data line DL. In some aspects, the pixel PX may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be a voltage lower than the third driving voltage VINT. The second driving voltage VDD may be a voltage higher than the third driving voltage VINT.

The pixel PX includes a plurality of transistors T1 to T6, a light emitting element ED, a first capacitor CP1, and a second capacitor CP2.

The light emitting element ED emits light according to a driving current Ids flowing through a channel of a first transistor T1. An amount of light emitted from the light emitting element ED may be proportional to the driving current Ids. The light emitting element ED may be positioned between a fourth transistor T4 and the first driving voltage line VSL. A first electrode of the light emitting element ED may be connected to a drain electrode of the fourth transistor T4, and a second electrode of the fourth transistor T4 may be connected to the first driving voltage line VSL. The first electrode of the light emitting element ED may be an anode electrode, and the second electrode of the light emitting element ED may be a cathode electrode. The light emitting element ED may be an organic light emitting diode including a first electrode, a second electrode, and an organic light emitting layer disposed between the first electrode and the second electrode, but embodiments of the present disclosure are not limited thereto. For example, the light emitting element ED may be an inorganic light emitting element including a first electrode, a second electrode, and an inorganic semiconductor disposed between the first electrode and the second electrode. In this case, the light emitting element ED may be a micro light emitting diode.

The first transistor T1 may be a driving transistor that controls a source-drain current Ids (hereinafter, referred to as “driving current”) flowing between a source electrode and a drain electrode according to a voltage applied to a gate electrode. The first transistor T1 includes a gate electrode connected to a first node N1, a source electrode connected to a drain electrode of a sixth transistor T6, and a drain electrode connected to a second node N2.

A second transistor T2 may be positioned between one electrode of the first capacitor CP1 and the data line DL. The second transistor T2 is turned on by the write scan signal of the write scan line GWL and connects one electrode of the first capacitor CP1 to the data line DL. Accordingly, the data voltage of the data line DL may be applied to one electrode of the first capacitor CP1. The second transistor T2 includes a gate electrode connected to the write scan line GWL, a source electrode connected to the data line DL, and a drain electrode connected to one electrode of the first capacitor CP1.

A third transistor T3 may be positioned between the first node N1 and the second node N2. The third transistor T3 is turned on by the control scan signal of the control scan line GCL and connects the first node N1 to the second node N2. Accordingly, since the gate electrode and the source electrode of the first transistor T1 are connected, the first transistor T1 may operate like a diode. The third transistor T3 includes a gate electrode connected to the control scan line GCL, a source electrode connected to the second node N2, and a drain electrode connected to the first node N1.

A fourth transistor T4 may be connected between the second node N2 and a third node N3. The fourth transistor T4 is turned on by the first emission control signal of the first emission control line EL1 and connects the second node N2 to the third node N3. Accordingly, the driving current of the first transistor T1 may be supplied to the light emitting element ED. The fourth transistor T4 includes a gate electrode connected to the first emission control line EL1, a source electrode connected to the second node N2, and a drain electrode connected to the third node N3.

A fifth transistor T5 may be positioned between the third node N3 and the third driving voltage line VIL. The fifth transistor T5 is turned on by the bias scan signal of the bias scan line EBL and connects the third node N3 to the third driving voltage line VIL. Accordingly, the third driving voltage VINT of the third driving voltage line VIL may be applied to the first electrode of the light emitting element ED. The fifth transistor T5 includes a gate electrode connected to the bias scan line EBL, a source electrode connected to the third node N3, and a drain electrode connected to the third driving voltage line VIL.

A sixth transistor T6 may be positioned between the source electrode of the first transistor T1 and the second driving voltage line VDL. The sixth transistor T6 is turned on by the second emission control signal of the second emission control line EL2 and connects the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and the other electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and the other electrode connected to the second driving voltage line VDL.

The first node N1 is a contact point of the gate electrode of the first transistor T1, the drain electrode of the third transistor T3, the other electrode of the first capacitor CP1, and one electrode of the second capacitor CP2. The second node N2 is a contact point of the drain electrode of the first transistor T1, the source electrode of the third transistor T3, and the source electrode of the fourth transistor T4. The third node N3 is a contact point of the drain electrode of the fourth transistor T4, the source electrode of the fifth transistor T5, and the first electrode of the light emitting element ED.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. Alternatively, each of some of the first to sixth transistors T1 to T6 may be a P-type MOSFET, and each of the remaining transistors may be an N-type MOSFET.

It is illustrated in FIG. 3 that the pixel PX includes the six transistors T1 to T6 and the two capacitors C1 and C2, but it should be noted that the equivalent circuit diagram of the pixel PX is not limited to that illustrated in FIG. 3. For example, the number of transistors and capacitors of the pixel PX is not limited to that illustrated in FIG. 3.

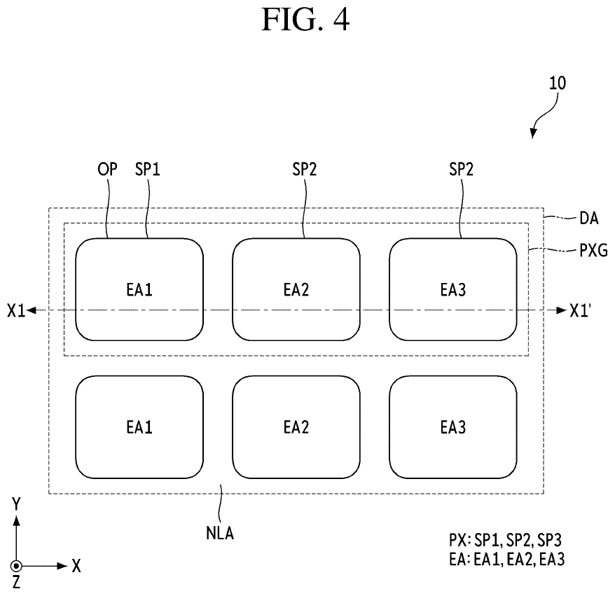

FIG. 4 is a plan view illustrating an arrangement of a plurality of pixels disposed in a display area in FIG. 2.

Referring to FIG. 4, in an embodiment, a plurality of pixels PX may be positioned in a portion overlapping the display area DAA. As an example, the pixel PX may include a first pixel SP1, a second pixel SP2, and a third pixel SP3, and the first pixel SP1, the second pixel SP2, and the third pixel SP3 may be spaced apart from each other.

In an embodiment, the first pixel SP1, the second pixel SP2, and the third pixel SP3 may form a pixel group PXG. The pixel group PXG may be a minimum unit that emits white light. However, the type and/or number of pixels PX that constitute the pixel group PXG may be variously changed according to the embodiments.

The first pixel SP1, the second pixel SP2, and the third pixel SP3 may include different light emitting areas EA. As an example, a first light emitting area EA1 included in the first pixel SP1 may emit red light of a first color, a second light emitting area EA2 included in the second pixel SP2 may emit green light of a second color, and a third light emitting area EA3 included in the third pixel SP3 may emit blue light of a third color, but are not limited thereto.

It is illustrated in the drawing that the size and shape of each of the first to third light emitting areas EA1, EA2, and EA3 are the same, but embodiments of the present disclosure are not limited thereto. The size and shape of each of the first to third light emitting areas EA1, EA2, and EA3 may be freely adjusted according to target or desired characteristics.

In an embodiment, the light emitting area EA may be defined by a light emitting opening OP. The light emitting opening OP may be defined by a first element insulating layer (‘DIL1’ in FIG. 5) described later.

The non-light emitting area NLA according to an embodiment may be positioned such that the non-light emitting area NLA surrounds each of the first to third light emitting areas EA1, EA2, and EA3. The non-light emitting area NLA may assist in preventing the light emitted from each of the first to third light emitting areas EA1, EA2, and EA3 from being mixed.

FIG. 5 is a cross-sectional view of a display device according to an embodiment taken along line X1-X1′ of FIG. 4. Hereinafter, a schematic cross-sectional structure of the display device 10 overlapping the first pixel SP1, the second pixel SP2, and the third pixel SP3 is illustrated in FIG. 5.

Referring to FIG. 5, the display device 10 may include a substrate SUB, a transistor layer TFTL, a display element layer EML, an encapsulation layer TFEL, and a color filter layer CFL.

The substrate SUB may be a base substrate or a base member. The substrate SUB may include a polymer resin such as, for example, polyimide (PI), a glass material, or a metal material, and may be a silicon substrate, a germanium substrate, or a silicon-germanium substrate. As an example, the glass substrate may be a rigid substrate that is not bent, and the polymer resin substrate may be a flexible substrate that may be bent or curved.

In an embodiment, a plurality of wells WA may be positioned in the substrate SUB. Based on the embodiment, the wells WA may also be omitted. The well WA may be an area doped with impurities.

As an example, when the substrate SUB includes the wells WA, the substrate SUB may be doped with a first type impurity, and the plurality of wells WA may be areas doped with a second type impurity. In an example in which the first-type impurity is a p-type impurity, the second-type impurity may be an n-type impurity. Alternatively, when the first-type impurity is an n-type impurity, the second-type impurity may be a p-type impurity.

The transistor layer TFTL may be positioned on the substrate SUB. The transistor layer TFTL may include a plurality of conductive layers and a plurality of insulating layers. As an example, the plurality of conductive layers may include a transistor layer TR, a connection electrode CNE, or the like, and the plurality of insulating layers may include an insulating layer ILD including an inorganic material, a via layer VA including an organic material, or the like.

In an embodiment, the transistor layer TR may include a first transistor layer TR1, a second transistor layer TR2, and a third transistor layer TR3.

The first transistor layer TR1 may be a transistor provided in the first pixel SP1. For example, the first transistor layer TR1 may be any one of the transistors illustrated in FIG. 3. The first transistor layer TR1 may include a first gate G1, a first source S1, and a first drain D1. A channel of the first transistor layer TR1 may be formed in a well WA between the first source S1 and the first drain D1. The first source S1 and the first drain D1 may be positioned in the well WA. A gate insulating layer GTI may be positioned between the first gate G1 and the well WA.

The second transistor layer TR2 may be a transistor provided in the second pixel SP2. The second transistor layer TR2 may include a second gate G2, a second source S2, and a second drain D2. The second source S2 and the second drain D2 may be positioned in the well WA. A channel of the second transistor layer TR2 may be formed in a well WA between the second source S2 and the second drain D2. A gate insulating layer GTI may be positioned between the second gate G2 and the well WA.

The third transistor layer TR3 may be a transistor provided in the third pixel SP3. The third transistor layer TR3 may include a third gate G3, a third source S3, and a third drain D3. The third source S3 and the third drain D3 may be positioned in the well WA. A channel of the third transistor layer TR3 may be formed in a well WA between the third source S3 and the third drain D3. A gate insulating layer GTI may be positioned between the third gate G3 and the well WA.

The insulating layer ILD may be positioned on the transistor layer TR. The insulating layer ILD may completely cover the transistor layers TR. The insulating layer ILD may include a plurality of stacked structures.

The insulating layer ILD may include an inorganic insulating material, for example, at least one of silicon nitride (e.g., Si₃N₄ or SiNx), silicon oxide (e.g., SiO₂ or SiOx), silicon oxynitride (e.g., SiON).

The connection electrode CNE may be positioned on the insulating layer ILD. A plurality of connection electrodes CNE may be formed, and each connection electrode CNE may be connected to the transistor layer TR through a contact hole penetrating through the insulating layer ILD. Specifically, the connection electrode CNE may be connected to at least one of the first drain D1 of the first transistor layer TR1, the second drain D2 of the second transistor layer TR2, or the third drain D3 of the third transistor layer TR3 through a contact hole penetrating through the insulating layer ILD.

The via layer VA may cover the connection electrode CNE. The via layer VA may planarize a step difference of a lower structure.

The via layer VA may include an organic material. As an example, the via layer VA may include an acrylic resin, an epoxy resin, a phenolic resin, a polyamide resin, or a polyimide resin.

The display element layer EML may be positioned on the transistor layer TFTL. The display element layer EML may include a metal pattern RM, a resonant auxiliary layer PVX, a first element insulating layer DIL1, a second element insulating layer DIL2, and a light emitting element ED.

The metal pattern RM may be positioned on the via layer VA in a portion overlapping the light emitting area EA. The metal pattern RM may reflect light emitted from the light emitting element ED or light incident from the outside.

The metal pattern RM may be connected to the connection electrode CNE through a contact hole penetrating through the via layer VA. For example, the metal pattern RM may be electrically connected to the transistor layer TR through the connection electrode CNE.

The metal pattern RM may be a metal layer including a metal such as, for example, silver (Ag), magnesium (Mg), aluminum (Al), platinum (Pt), palladium (Pd), gold (Au), nickel (Ni), neodymium (Nd), iridium (Ir), chromium (Cr), or a compound thereof. In some aspects, the metal pattern RM may include titanium (Ti) and titanium nitride (TiN) positioned at an upper or lower end of the metal layer. In some aspects, the metal pattern RM may further include a metal oxide layer (e.g., a transparent conductive material) positioned at the upper or lower end of the metal layer.

A plurality of metal patterns RM may be formed and may be positioned in a portion overlapping the first to third light emitting areas EA1, EA2, and EA3. The metal patterns RM overlapping each of the first to third light emitting areas EA1, EA2, and EA3 may be spaced apart from each other.

The resonant auxiliary layer PVX may be positioned on the metal pattern RM. The resonant auxiliary layer PVX may entirely cover an upper surface of the metal pattern RM, and may also cover a side surface of the metal pattern RM based on the embodiment.

The resonant auxiliary layer PVX may include an inorganic insulating material. For example, the resonant auxiliary layer PVX may include at least one of silicon nitride (e.g., Si₃N₄ or SiNx), silicon oxide (e.g., SiO₂ or SiOx), and silicon oxynitride (e.g., SiON).

The resonant auxiliary layer PVX may reinforce a resonant structure of the light emitting element ED. As an example, the resonant auxiliary layer PVX may have a height or thickness that may cause constructive interference when light emitted from the light emitting element ED is reflected by the metal pattern RM. Accordingly, the display device 10 according to an embodiment may increase a light emitting efficiency of the light emitting element ED.

The resonant auxiliary layer PVX may include a first resonant auxiliary layer PVX1 overlapping the first light emitting area EA1, a second resonant auxiliary layer PVX2 overlapping the second light emitting area EA2, and a third resonant auxiliary layer PVX3 overlapping the third light emitting area EA3. The first resonant auxiliary layer PVX1, the second resonant auxiliary layer PVX2, and the third resonant auxiliary layer PVX3 may be spaced apart from each other.

The first resonant auxiliary layer PVX1, the second resonant auxiliary layer PVX2, and the third resonant auxiliary layer PVX3 may have different thicknesses. As an example, the second resonant auxiliary layer PVX2 may have a thicker thickness than the first resonant auxiliary layer PVX1, and the third resonant auxiliary layer PVX3 may have a thicker thickness than the second resonant auxiliary layer PVX2. However, this is an example, and embodiments of the present disclosure are not limited thereto.

The light emitting element ED may be positioned on the resonant auxiliary layer PVX. The light emitting element ED may include a first light emitting element ED1 overlapping the first light emitting area EA1, a second light emitting element ED2 overlapping the second light emitting area EA2, and a third light emitting element ED3 overlapping the third light emitting area EA3. The first light emitting element ED1 may include an anode electrode AE, a first light emitting layer ELL1, and a cathode electrode CE, the second light emitting element ED2 may include an anode electrode AE, a second light emitting layer ELL2, and a cathode electrode CE, and the third light emitting element ED3 may include an anode electrode AE, a third light emitting layer ELL3, and a cathode electrode CE.

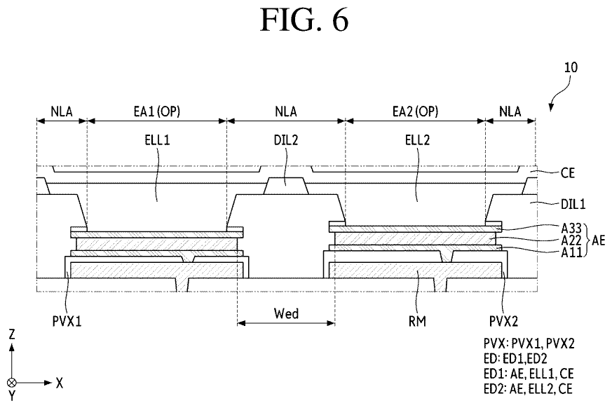

FIG. 6 is an enlarged cross-sectional view of a display element layer overlapping a first light emitting area and a second light emitting area in FIG. 5.

Referring to FIGS. 5 and 6, the anode electrode AE may be positioned on the resonant auxiliary layer PVX. The anode electrode AE may be positioned in a portion overlapping the first light emitting area EA1, the second light emitting area EA2, and the third light emitting area EA3, and the anode electrodes AE positioned in portions overlapping each of the first light emitting area EA1, the second light emitting area EA2, and the third light emitting area EA3 may be spaced apart from each other.

The anode electrodes AE positioned in the portions overlapping each of the first light emitting area EA1, the second light emitting area EA2, and the third light emitting area EA3 may be positioned at different heights. As an example, the anode electrode AE positioned in the portion overlapping the first light emitting area EA1 may be positioned relatively closest to the substrate SUB, and the anode electrode AE positioned in the portion overlapping the third light emitting area EA3 may be positioned relatively farthest from the substrate SUB. This may be caused by a difference in thickness of the resonant auxiliary layer PVX positioned at the bottom.

The anode electrode AE may be a conductive material including silver (Ag).

The anode electrode AE may include a first layer A11, a second layer A22, and a third layer A33. The first layer A11, the second layer A22, and the third layer A33 may be stacked in sequence.

The first layer A11 may be positioned in contact with the resonant auxiliary layer PVX. It is illustrated in the drawing that the first layer A11 covers only an upper surface of the resonant auxiliary layer PVX, but embodiments of the present disclosure are not limited thereto. The first layer A11 may entirely cover the resonant auxiliary layer PVX.

The first layer A11 may be electrically connected to the metal pattern RM through a contact hole penetrating through the resonant auxiliary layer PVX.

The first layer A11 may include a transparent conductive material (TCO). As an example, the first layer A11 may include Indium Tin Oxide (ITO) or Indium Zinc Oxide (IZO).

The second layer A22 may be positioned on the first layer A11. The second layer A22 may include a metal with high reflectivity and may improve the light emitting efficiency of the display device 10. As an example, the second layer A22 may include silver (Ag).

The display device 10 according to an embodiment may pattern the second layer A22 by performing a cleaning process after fluorine (F)-based plasma treatment in a fabricating process. The fabricating process will be described later.

The third layer A33 may be positioned on the second layer A22.

The third layer A33 may include a transparent conductive material (TCO). As an example, the third layer A33 may include Indium Tin Oxide (ITO) or Indium Zinc Oxide (IZO), but embodiments of the present disclosure are not limited thereto.

A thickness of the second layer A22 may be greater than a thickness of the first layer A11 and a thickness of the third layer A33. The meaning of thickness described herein may have the same meaning as height.

The display device 10 according to an embodiment may pattern the first layer A11 and the third layer A33 by performing a dry etching process in the fabricating process. The fabricating process will be described later.

The display device 10 according to an embodiment may be applied to a high-resolution electronic device. This may mean that a plurality of light emitting elements ED are positioned within a small area. In other words, the display device 10 according to an embodiment may include an implementation in which a gap between the first light emitting element ED1, the second light emitting element ED2, and the third light emitting element ED3 be formed narrowly.

In an embodiment, a gap between adjacent light emitting elements ED may be defined as a gap between adjacent anode electrodes AE. Specifically, the gap between the adjacent light emitting elements ED may be defined as a gap between adjacent second layers A22. That is, the gap between the adjacent second layers A22 in the first direction (X-axis direction) may be defined as an element gap Wed of the first to third light emitting elements ED1, ED2, and ED3.

In other words, since the display device 10 according to an embodiment is applied to the high-resolution electronic device, the element gap Wed may be formed narrowly. As an example, the range of element gap Wed applicable to high-resolution products may be 1.86 micrometers or less. However, this is an example, and embodiments of the present disclosure are not limited thereto.

The first insulating layer DIL1 may be positioned on the via layer VA in a portion overlapping the non-light emitting area NLA. The first insulating layer DIL1 may cover edges of the resonant auxiliary layer PVX and the anode electrode AE.

The first insulating layer DIL1 may define a light emitting opening OP and may be positioned such that the first insulating layer DIL1 surrounds the light emitting opening OP. The first insulating layer DIL1 may expose the anode electrode AE in a portion overlapping the light emitting opening OP.

The first insulating layer DIL1 may include an organic material or an inorganic insulating material.

As an example, when the first insulating layer DIL1 includes the organic material, the first insulating layer DIL1 may include an acryl resin, an epoxy resin, a phenolic resin, a polyamide resin, a polyimide resin, or the like.

As an example, when the first insulating layer DIL1 includes the inorganic insulating material, the first insulating layer DIL1 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The second insulating layer DIL2 may be positioned on the first insulating layer DIL1 in the portion overlapping the non-light emitting area NLA. The second insulating layer DIL2 may serve as a separator that separates the first to third light emitting layers ELL1, ELL2, and ELL3.

The second insulating layer DIL2 may include an organic material or an inorganic insulating material.

As an example, when the second insulating layer DIL2 includes the organic material, the second insulating layer DIL2 may include an acryl resin, an epoxy resin, a phenolic resin, a polyamide resin, a polyimide resin, or the like.

As an example, when the second insulating layer DIL2 includes the inorganic insulating material, the second insulating layer DIL2 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

In an example in which the first insulating layer DIL1 and the second insulating layer DIL2 include the same material, the first insulating layer DIL1 and the second insulating layer DIL2 may be integrally formed.

A residual pattern TP may be positioned between the anode electrode AE and the first insulating layer DIL1 in the third direction (Z-axis direction). The residual pattern TP may be positioned such that the residual pattern TP surrounds the light emitting opening OP.

The residual pattern TP is used as a temporary protective layer to protect the anode electrode AE from the etching process during the fabricating process of the display device 10, and a portion of the residual pattern TP may be removed by a subsequent etching process, while another portion may remain in the form currently illustrated.

The residual pattern TP may include a transparent conductive material (TCO). As an example, the residual pattern TP may include Indium Tin Oxide (ITO) or Indium Zinc Oxide (IZO).

The residual pattern TP may be positioned in portions overlapping the first light emitting area EA1, the second light emitting area EA2, and the third light emitting area EA3, and the residual patterns TP positioned in the portions overlapping each of the first light emitting area EA1, the second light emitting area EA2, and the third light emitting area EA3 may be positioned at different heights. As an example, the residual pattern TP positioned in the portion overlapping the first light emitting area EA1 may be positioned relatively closest to the substrate SUB, and the residual pattern TP positioned in the portion overlapping the third light emitting area EA3 may be positioned relatively farthest from the substrate SUB. This may be caused by a difference in thickness of the resonant auxiliary layer PVX positioned at the bottom.

The light emitting layer ELL may be positioned on the anode electrode AE. The light emitting layer ELL may include a first light emitting layer ELL1 overlapping the first light emitting area EA1, a second light emitting layer ELL2 overlapping the second light emitting area EA2, and a third light emitting layer ELL3 overlapping the third light emitting area EA3. The first light emitting layer ELL1, the second light emitting layer ELL2, and the third light emitting layer ELL3 may be spaced apart from each other, with the second insulating layer DIL2 interposed between the first light emitting layer ELL1, the second light emitting layer ELL2, and the third light emitting layer ELL3. However, the present specification is not limited thereto, and based on the embodiment, the first light emitting layer ELL1, the second light emitting layer ELL2, and the third light emitting layer ELL3 may also be integrally formed.

For example, the first light emitting layer ELL1, the second light emitting layer ELL2, and the third light emitting layer ELL3 may emit light of the same color or may emit light of different colors.

As an example, when the first light emitting layer ELL1, the second light emitting layer ELL2, and the third light emitting layer ELL3 emit light of different colors, the first light emitting layer ELL1 may emit red light, the second light emitting layer ELL2 may emit green light, and the third light emitting layer ELL3 may emit blue light. However, the present specification is not limited thereto.

As an example, when the first light emitting layer ELL1, the second light emitting layer ELL2, and the third light emitting layer ELL3 emit light of the same color, the first light emitting layer ELL1, the second light emitting layer ELL2, and the third light emitting layer ELL3 may emit at least one of blue light or white light.

The cathode electrode CE may be positioned on the light emitting layer ELL. The cathode electrode CE may be formed to overlap the light emitting area EA and the non-light emitting area NLA. In other words, the cathode electrode CE may be a common electrode.

The cathode electrode CE may include a transparent conductive material (TCO) such as, for example, ITO or IZO capable of transmitting light, or a semi-transmissive conductive material such as, for example, magnesium (Mg), silver (Ag), or an alloy of magnesium (Mg) and silver (Ag).

The encapsulation layer TFEL may be positioned on the display element layer EML. The encapsulation layer TFEL may prevent oxygen or moisture from permeating into the display element layer EML and may alleviate physical impact applied to the display element layer EML.

The encapsulation layer TFEL may include a first encapsulation layer TFE1, a second encapsulation layer TFE2, and a third encapsulation layer TFE3. The first encapsulation layer TFE1 may be disposed on the cathode electrode CE, the second encapsulation layer TFE2 may be disposed on the first encapsulation layer TFE1, and the third encapsulation layer TFE3 may be disposed on the second encapsulation layer TFE2.

The first encapsulation layer TFE1 may cover the display element layer EML with the same thickness along a profile of the lower structure. The first encapsulation layer TFE1 may include an inorganic insulating material. As an example, the first encapsulation layer TFE1 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

The second encapsulation layer TFE2 may planarize a step difference of the lower structure. The second encapsulation layer TFE2 may include an organic material. As an example, the second encapsulation layer TFE2 may be an organic film formed of an acrylic resin, an epoxy resin, a phenolic resin, a polyamide resin, or a polyimide resin.

The third encapsulation layer TFE3 may include an inorganic insulating material. As an example, the third encapsulation layer TFE3 may include silicon nitride (e.g., Si₃N₄ or SiNx), silicon oxide (e.g., SiO₂ or SiOx), silicon oxynitride (e.g., SiON), titanium oxide, aluminum oxide, or other inorganic insulating materials.

In an embodiment, the color filter layer CFL may be positioned on the encapsulation layer TFEL. The color filter layer CFL may include a first color filter CF1, a second color filter CF2, and a third color filter CF3.

In an embodiment, the first color filter CF1 may be positioned in a portion overlapping the first light emitting area EA1. The first color filter CF1 may transmit light of a first color (e.g., light in a red wavelength band). Accordingly, the first color filter CF1 may transmit the light of the first color among light emitted from the first light emitting element ED1.

In an embodiment, the second color filter CF2 may be positioned in a portion overlapping the second light emitting area EA2. The second color filter CF2 may transmit light of a second color (e.g., light in a green wavelength band). Accordingly, the second color filter CF2 may transmit the light of the second color among light emitted from the second light emitting element ED2.

In an embodiment, the third color filter CF3 may be positioned in a portion overlapping the third light emitting area EA3. The third color filter CF3 may transmit light of a third color (e.g., light in a blue wavelength band). Accordingly, the third color filter CF3 may transmit the light of the third color among light emitted from the third light emitting element ED3.

Accordingly, the light of the first color (e.g., red light) may be emitted from the first light emitting area EA1, the light of the second color (e.g., green light) may be emitted from the second light emitting area EA2, and the light of the third color (e.g., blue light) may be emitted from the third light emitting area EA3.

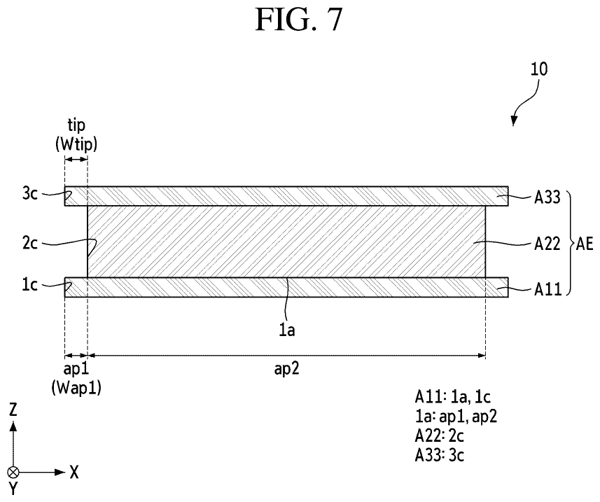

FIG. 7 is an enlarged cross-sectional view of an anode electrode of FIG. 6.

Referring to FIG. 7 in addition to FIGS. 1 to 6, the first layer A11 of the anode electrode AE included in the display device 10 may have an upper surface 1a and a side surface 1c. The upper surface 1a of the first layer A11 may be one surface in contact with the second layer A22.

In an embodiment, a side surface 2c of the second layer A22 may be more depressed than the side surface 1c of the first layer A11 in the first direction (X-axis direction). Accordingly, a step-shaped level difference may be formed between the first layer A11 and the second layer A22 of the anode electrode AE included in the display device 10.

It is illustrated in the drawing that the side surface 2c of the second layer A22 is one surface perpendicular to the third direction (Z-axis direction), but embodiments of the present disclosure are not limited thereto. Based on the embodiment, the side surface 2c of the second layer A22 may be a parallel inclined surface between the first direction (X-axis direction) and the third direction (Z-axis direction).

In an embodiment, the upper surface 1a of the first layer A11 may include a first portion ap1 and a second portion ap2. The first portion ap1 may be a portion that is exposed and not covered by the second layer A22, and the second portion ap2 may be a portion that is in contact with and covered by the second layer A22.

In an embodiment, a width Wap1 of the first portion ap1 may be 0.1 micrometers or less. The width Wap1 of the first portion ap1 formed to be 0.1 micrometers or less may be a major factor in forming a high-resolution product. As a comparative example, when the width Wap1 of the first portion ap1 is formed to be larger than the range described herein, the element gap Wed of the light emitting elements ED may be outside the range applicable to the high-resolution products, and thus, it may be difficult to form the required resolution.

The third layer A33 of the anode electrode AE may be positioned in contact with the second layer A22.

In an embodiment, a side surface 3c of the third layer A33 may more protrude than the side surface 2c of the second layer A22 in the first direction (X-axis direction). Accordingly, the third layer A33 may have a protruding portion tip that protrudes further in the first direction DR1 than the side surface 2c of the second layer A22. The protruding portion tip included in the third layer A33 may overlap the residual pattern TP in the third direction (Z-axis direction).

In an embodiment, a width Wtip of the protruding portion tip may be 0.1 micrometers or less. The width Wtip of the protruding portion tip formed to be 0.1 micrometers or less may be a major factor in forming a high-resolution product. As a comparative example, when the width Wtip of the protruding portion tip is formed to be larger than the range described herein, the element gap Wed of the light emitting elements ED may be outside the range applicable to the high-resolution products, and thus, it may be difficult to form the required resolution.

In general, when patterning the anode electrode AE by performing a wet etching process, the first layer A11, the second layer A22, and the third layer A33 including different materials may have different etching rates, and due to this, the second layer A22 of the anode electrode AE may be formed to be more depressed by 0.3 micrometers or more in the first direction (X-axis direction) than the first layer A11 and the third layer A33. Due to the nature of the wet etching process that performs etching using a liquid etching solution, it may be difficult to adjust the depressed width of the second layer A22 to 0.3 micrometers or less.

As another example, when the anode electrode AE including silver (Ag) is patterned by performing a dry etching process during the fabricating process, fabricating efficiency may be reduced because a reaction temperature of silver (Ag) ions is performed above 500 degrees Celsius.

The display device 10 according to an embodiment is characterized by patterning the anode electrode AE through the plasma treatment and cleaning processes during the fabricating process. The display device 10 according to an embodiment may minimize an overhang structure of the anode electrode AE by patterning the anode electrode AE through the plasma treatment and cleaning processes during the fabricating process. Specifically, the anode electrode AE included in the display device 10 may be formed such that the width Wap1 of the first portion ap1 included in the first layer A11 and the width Wtip of the protruding portion tip included in the third layer A33 are 0.1 micrometers or less. Accordingly, the display device 10 according to an embodiment may form the element gap Wed between the adjacent light emitting elements ED within the range applicable to high-resolution products and may have a resolution of at least 1700 ppi or more.

The anode electrode AE may have various shapes based on the patterning process conditions.

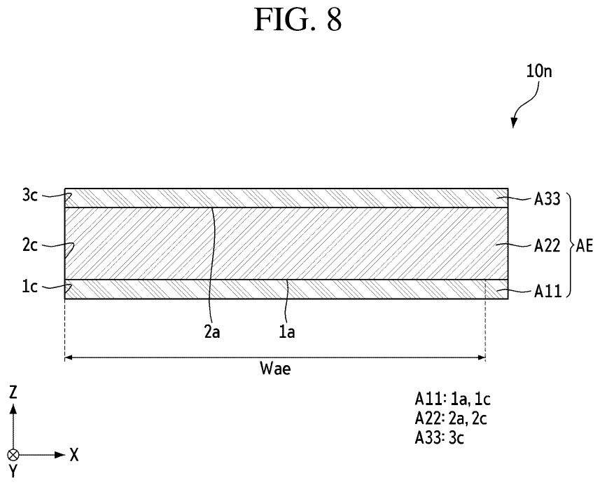

FIG. 8 is an enlarged cross-sectional view of an anode electrode of FIG. 5 according to another embodiment.

Referring to FIG. 8 in addition to FIGS. 1 to 7, a first layer A11 of an anode electrode AE included in a display device 10n may have an upper surface 1a and a side surface 1c. The upper surface 1a of the first layer A11 may be one surface in contact with the second layer A22. The upper surface 1a of the first layer A11 included in the display device 10n may be entirely covered by the second layer A22.

The second layer A22 of the anode electrode AE may be positioned on the upper surface 1a. The second layer A22 included in the display device 10n may include an upper surface 2a and a side surface 2c.

The side surface 2c of the second layer A22 included in the display device 10n may be positioned on the same line as the side surface 1c of the first layer A11. That is, the side surface 1c of the first layer A11 and the side surface 2c of the second layer A22 of the anode electrode AE included in the display device 10n may not include a level difference and may be positioned such that the side surface 1c and the side surface 2c are aligned.

A third layer A33 may be positioned in contact with the second layer A22. The upper surface 2a of the second layer A22 included in the display device 10n may be entirely covered by the third layer A33.

A side surface 3c of the third layer A33 included in the display device 10n may be positioned on the same line as the side surface 2c of the second layer A22. That is, the side surface 2c of the second layer A22 and the side surface 3c of the third layer A33 of the anode electrode AE included in the display device 10n may not include a level difference and may be positioned such that the side surface 2c and the side surface 3c are aligned.

In other words, the first layer A11, the second layer A22, and the third layer A33 of the anode electrode AE included in the display device 10n may have the same width Wae in the first direction (X-axis direction). However, the meaning of the same width Wae described herein may include a value within a process error of 5%.

The display device 10n may not include an overhang structure of the anode electrode AE by forming the anode electrode AE through the plasma treatment and cleaning processes during the fabricating process. As an example, the anode electrode AE included in the display device 10n may not include the overhang structure of the anode electrode AE by forming the first layer A11, the second layer A22, and the third layer A33 such that the width of the first layer A11, the width of the second layer A22, and the width of the third layer A33 are the same. Due to this, the display device 10n may form the element gap Wed between the adjacent light emitting elements ED within a range applicable to high-resolution products. As an example, the element gap Wed between the light emitting elements ED included in the display device 10n may be 1.86 micrometers or less.

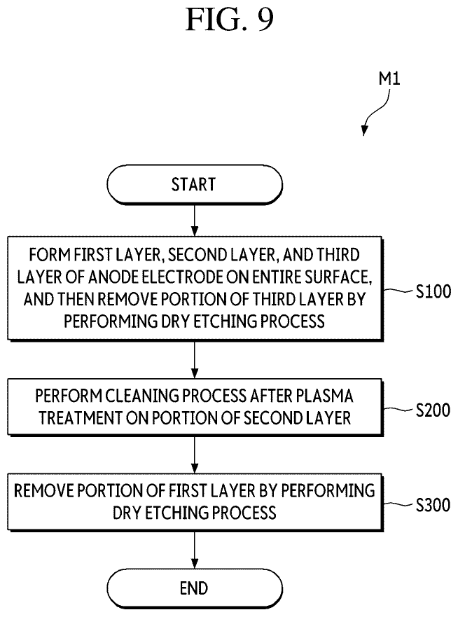

FIG. 9 is a flowchart illustrating a method for fabricating an anode electrode according to an embodiment.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing and forming the element, and the like in accordance with example aspects described herein.

Referring to FIG. 9, a method M1 for fabricating a display device 10 according to an embodiment may include a step (S100) of forming a first layer, a second layer, and a third layer of an anode electrode on an entire surface, and then removing a portion of the third layer by performing a dry etching process, a step (S200) of performing a cleaning process after plasma treatment on a portion of the second layer, and a step (S300) of removing a portion of the first layer by performing a dry etching process.

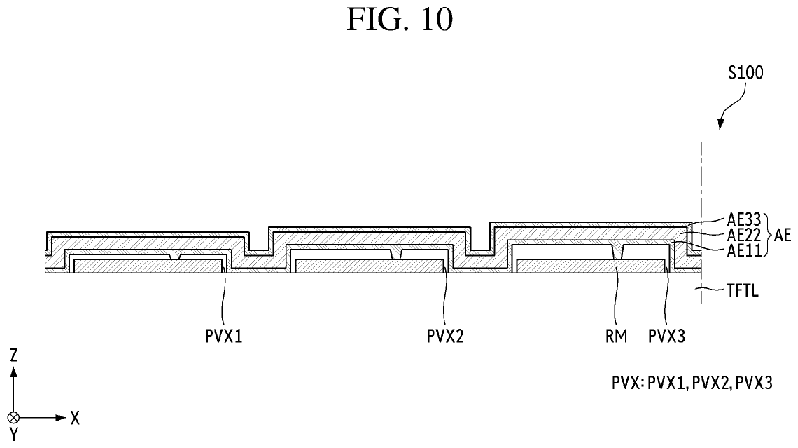

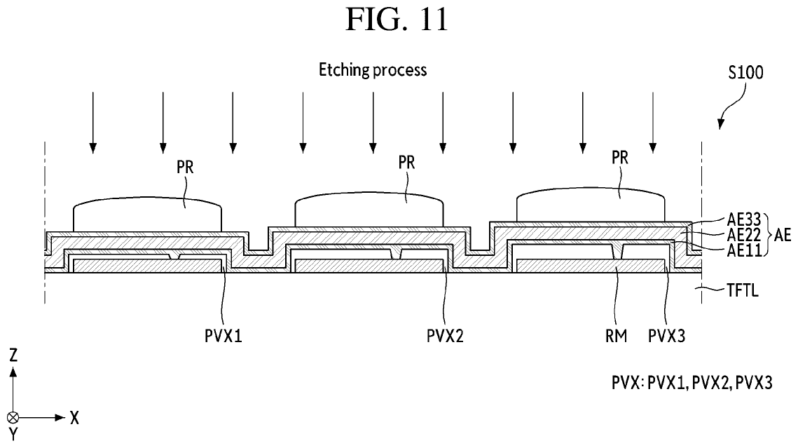

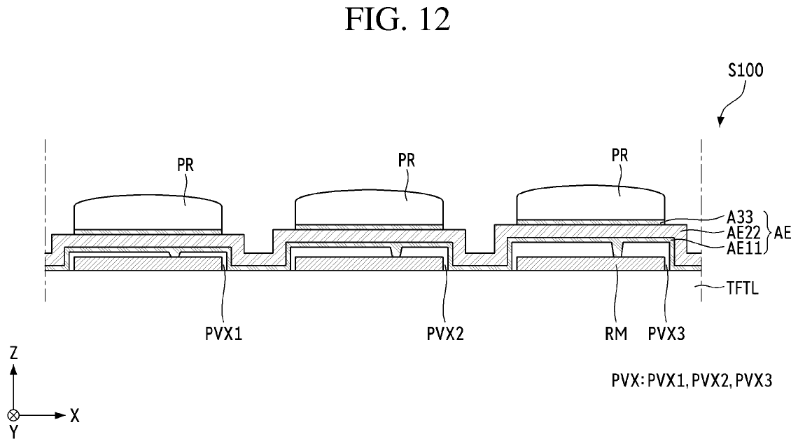

FIGS. 10 to 12 are cross-sectional views illustrating step S100 of FIG. 9.

The step (S100) of forming a first layer, a second layer, and a third layer of an anode electrode on an entire surface, and then removing a portion of the third layer by performing a dry etching process will be described with reference to FIGS. 10 to 12.

First, the method may include forming a plurality of metal patterns RM on a transistor layer TFTL, and forming a resonant auxiliary layer PVX covering each metal pattern RM. In the present process, thicknesses of the first resonant auxiliary layer PVX1, the second resonant auxiliary layer PVX2, and the third resonant auxiliary layer PVX3 may be differently formed. The redundant descriptions will be omitted.

Next, the method may include sequentially forming a first conductive layer AE11, a second conductive layer AE22, and a third conductive layer AE33 of the anode electrode AE on the resonant auxiliary layer PVX. The first conductive layer AE11, the second conductive layer AE22, and the third conductive layer AE33 may be deposited on the entire surface. The first conductive layer AE11 and the third conductive layer AE33 may each include a transparent conductive material (TCO), and the second conductive layer AE22 may include silver (Ag).

The first conductive layer AE11, the second conductive layer AE22, and the third conductive layer AE33 described herein may be formed as the first layer A11, the second layer A22, and the third layer A33 illustrated in FIGS. 5 to 8 through the processes described herein. That is, in the present specification, the first conductive layer AE11 and the first layer A11, the second conductive layer AE22 and the second layer A22, and the third conductive layer AE33 and the third layer A33 may each mean the same configuration.

Although not illustrated in the drawings, the method may include positioning a temporary protective layer TPL on the third conductive layer AE33 of the anode electrode AE based on the embodiment. The temporary protective layer TPL is in contact with and covers an upper surface of the anode electrode AE and thus protects the anode electrode AE from damage during a subsequent etching process. In an example in which the temporary protective layer TPL is included, the temporary protective layer TPL may be formed in the shape of the residual pattern TP as illustrated in FIGS. 5 and 6 through a subsequent process.

Next, the method may include forming a photoresist PR on the third conductive layer AE33, and then performing an etching process. In the present process, a plurality of photoresists PR may be formed and spaced apart from each other. The etching process of the present process may be performed as a dry etching process.

As an example, the dry etching process may be performed through a reactive ion etching (RIE) process using reactive gases such as, for example, CHF₃, CH₃F, CH₂F₂, CHF₆, CF₄, C₂F₆, and C₃F₆, and sputtering gases such as, for example, Ar, and O₂/Ar. In this case, an inductively coupled plasma (ICP) source or a capacitively coupled plasma (CCP) source may be used as a plasma source.

In the present process, a portion of the third conductive layer AE33 that does not overlap the photoresist PR may be removed, thereby exposing a portion of the second conductive layer AE22 positioned in a portion that does not overlap the photoresist PR.

As a result, the third layer A33 illustrated in FIGS. 5 to 8 may be formed.

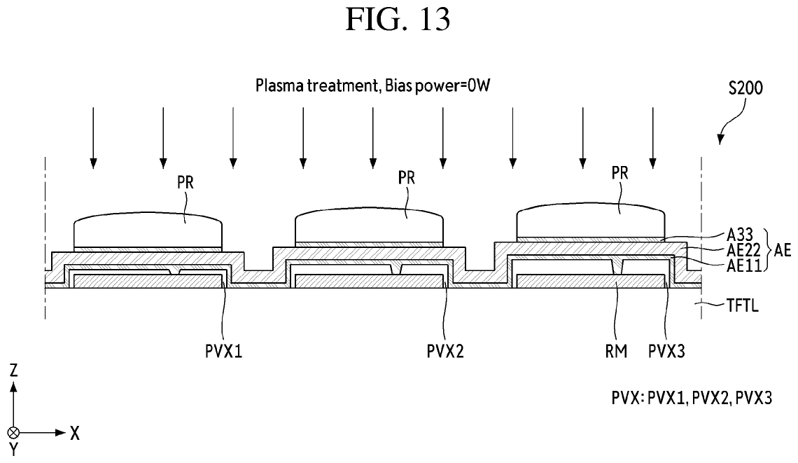

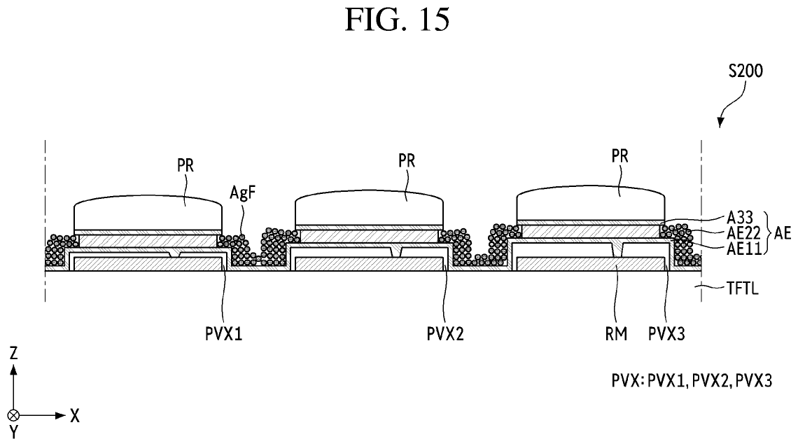

FIGS. 13 and 15 are cross-sectional views illustrating a plasma treatment process during step S200 of FIG. 9 and FIGS. 16 to 18 are cross-sectional views illustrating a cleaning process during step S200 of FIG. 9.

The step (S200) of performing a cleaning process after plasma treatment on a portion of the second layer will be described with reference to FIGS. 13 to 18. In the present process, the photoresist PR may be maintained as it was formed in the previous step.

First, the method may include performing a plasma treatment process on the second conductive layer AE22. The present process may use at least one of plasma etching (PE), reactive ion etching (RIE), and inductively coupled plasma (ICP) equipment.

In the present process, the plasma may include fluorine-based gas and oxygen-based gas. As an example, the present process may be performed by mixing a halogen gas containing fluorine (F), such as, for example, CHF₃, CH₃F, CH₂F₂, CHF₆, CF₄, C₂F₆, C₃F₆, and F₂, and oxygen gas (O₂). In the present process, the fluorine (F) gas may be used to undergo a radical reaction with silver (Ag), and the oxygen (O) gas may be used to vaporize carbon (C) into carbon monoxide (CO) and carbon dioxide (CO₂).

In the present process, process parameters for generating plasma may include gas flow rate, pressure, plasma source power, plasma bias power, time, and temperature.

In the present process, the bias power may be performed with a value of ‘0 W’, and the gas flow rate, the pressure, the plasma source power, the time, and the temperature other than the bias power may be provided in any suitable range that is commonly used.

In general, in the plasma treatment process, the bias power is a low-frequency power source that may increase an energy of reactive ions. In an example in which the bias power is set to be high in the present process, the energy of silver ions included in the anode electrode may increase, which may enhance physical etching characteristics of the silver ions.

The process of manufacturing the display device 10 according to an embodiment may minimize the physical etching characteristics of silver (Ag) included in the anode electrode AE and improve chemical reaction characteristics by zeroing the bias power (bias power=0 W).

As illustrated in FIG. 15, through the present process, most of the silver (Ag) particles included in the second conductive layer AE22 that does not overlap the photoresist PR may be formed into silver fluoride (AgF).

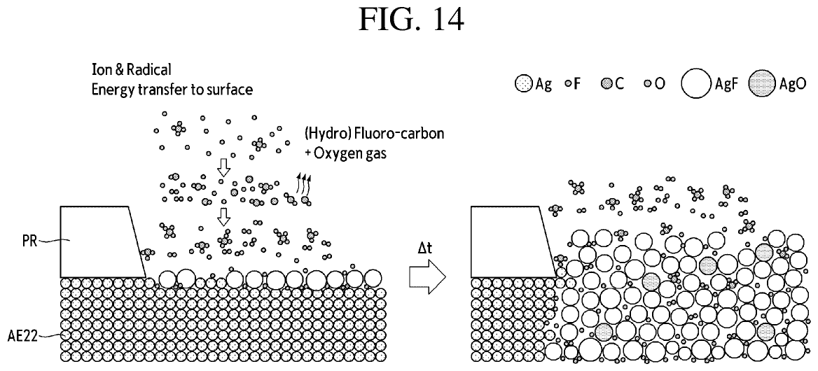

FIG. 14 is a cross-sectional view illustrating a mechanism by which silver fluoride is formed.

Referring to FIG. 14, in the present process, the method may include forming silver fluoride (AgF) by performing an ion radical reaction on fluorocarbon gas and oxygen gas.

Specifically, the aforementioned ion radical reaction may start from the surface of the second conductive layer AE22 that does not overlap the photoresist PR, and as a reaction time Δt elapses, a radical chain reaction may proceed into the second conductive layer AE22. As described herein, maintaining the bias power at zero may be a key factor in the present process.

In the present process, most of the silver (Ag) particles that do not overlap the photoresist PR may be formed into silver fluoride (AgF), and some silver oxide (AgO) may also form between silver fluoride (AgF). Both silver fluoride (AgF) and silver oxide (AgO) may have high solubility properties in a cleaning solution of the subsequent process. In some aspects, carbon (C) gas may react with oxygen gas (O₂) to form carbon monoxide (CO) or/and carbon dioxide (CO₂). A reaction rate of the present process may be accelerated as a proportion of fluorine in the fluorocarbon gas increases.

In an intermediate step of the present process, film density of the second conductive layer AE22 may temporarily decrease as silver fluoride (AgF) or silver oxide (AgO) is formed. Due to this, in the intermediate step of the present process, a portion of the second conductive layer AE22 that does not overlap the photoresist PR may have a swelling characteristic.

The reaction of the present process may be chemically expressed as follows.

Ag+F*->AgF (water soluble, 1790 g/L)

For convenience of explanation, the present process is illustrated as being performed as a single process, but embodiments of the present disclosure are not limited thereto. The present process may be performed by dividing the present process into a plurality of processes by adjusting the process parameter values to form a fine structure. In an example in which the present process is performed by dividing the present process into the plurality of processes, the second conductive layer AE22 may be finely patterned by dividing the second conductive layer into a plurality of layers.

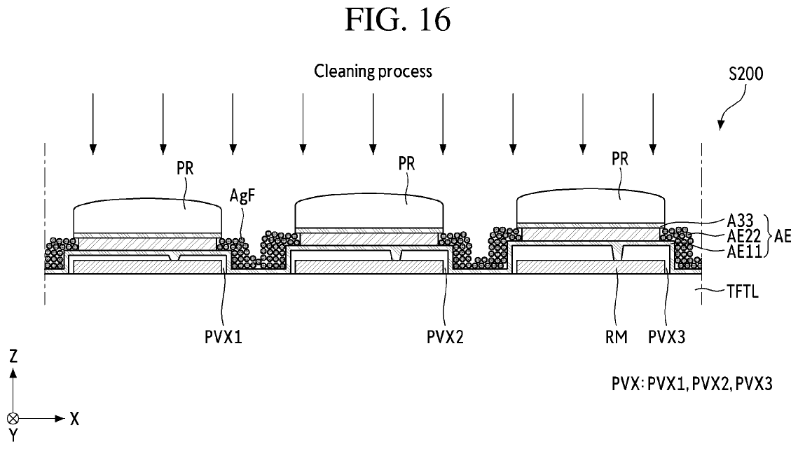

FIGS. 16 to 18 are cross-sectional views illustrating a cleaning process during step S200 of FIG. 9.

Next, referring to FIGS. 16 to 18, the method may include performing a cleaning process. In the present process, silver fluoride (AgF) and silver oxide (AgO) may have high solubility in the cleaning solution (e.g., organic stripper, deionized water (DI), or the like). Due to this, silver fluoride (AgF) and silver oxide (AgO) may be easily removed by the cleaning solution without any additional process. Accordingly, in the present process, silver fluoride (AgF) or some silver oxide (AgO, not illustrated) may be completely removed.

In this way, the second layer A22 illustrated in FIGS. 5 to 8 may be formed by patterning the second conductive layer AE22 of the anode electrode AE.

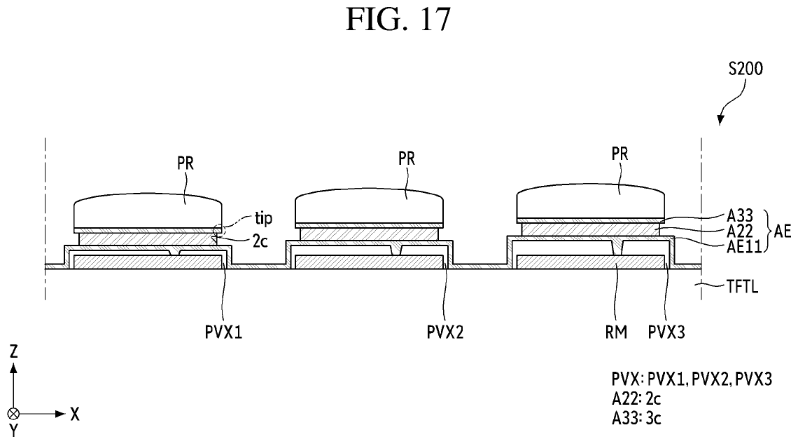

In some embodiments, the third layer A33 of the anode electrode AE may have a protruding portion tip that protrudes further in the first direction (X-axis direction) compared to the side surface 2c of the second layer A22 as illustrated in FIG. 17, and a width of the protruding portion tip may be 0.1 micrometers or less. The redundant descriptions will be omitted.

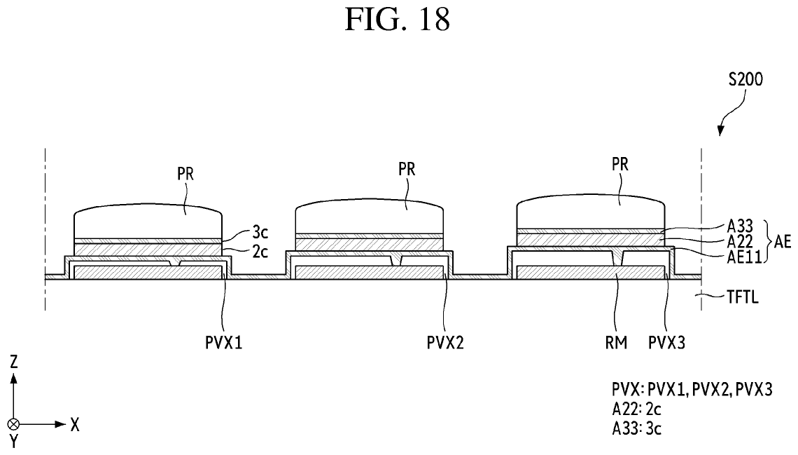

In some embodiments, the third layer A33 of the anode electrode AE may have a side surface 3c of the third layer A33 that is positioned on the same line as the side surface 2c of the second layer A22, as illustrated in FIG. 18.

The shapes illustrated in FIGS. 17 and 18 may be formed into different shapes by performing the step (S200) of performing the cleaning process after plasma treatment on a portion of the second layer in micro-steps. Hereinafter, the subsequent process is described in the form illustrated in FIG. 17.

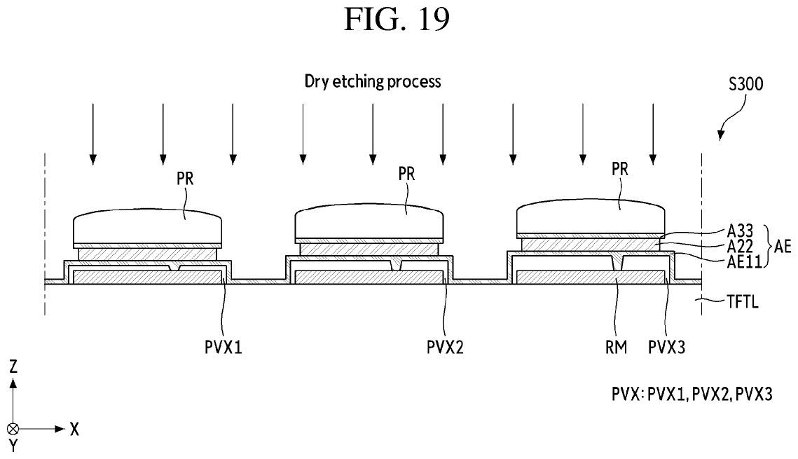

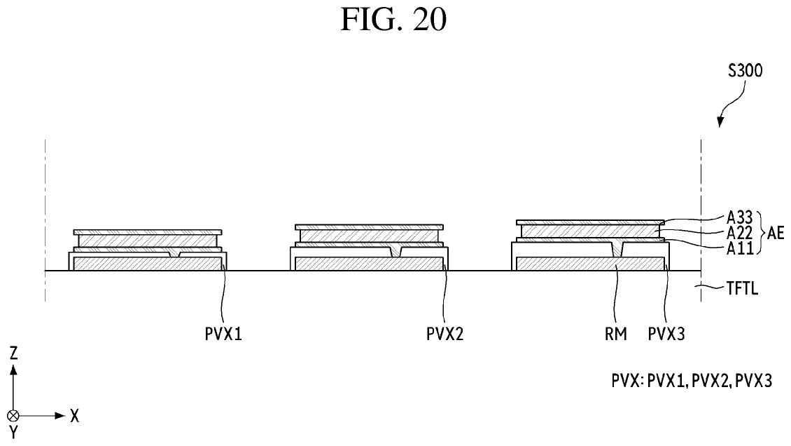

FIGS. 19 and 20 are cross-sectional views illustrating step S300 of FIG. 9.

The step (S300) of removing a portion of the first layer by performing a dry etching process will be described with reference to FIGS. 19 and 20. In the present process, the photoresist PR may be maintained as it was formed in the previous step.

Next, the method may include performing an etching process. As an example, the etching process of the present process may be performed as a dry etching process.

In the present process, a portion of the first conductive layer AE11 that does not overlap the photoresist PR may be removed, thereby forming the first layer A11 illustrated in FIGS. 5 to 8.

Referring again to FIGS. 1 to 20, the display device 10 according to an embodiment performs the plasma treatment process by zeroing the bias power (bias power=0) and then performs the cleaning process, thereby patterning the anode electrode AE including silver (Ag). Accordingly, the display device 10 according to an embodiment may have ease of fabrication.

In some aspects, the display device 10 according to an embodiment may form the width of the protruding portion tip of the anode electrode AE including silver (Ag) to be 0.1 micrometers or less, thereby forming the element gap Wed between the light emitting elements ED within the range applicable to high-resolution products.

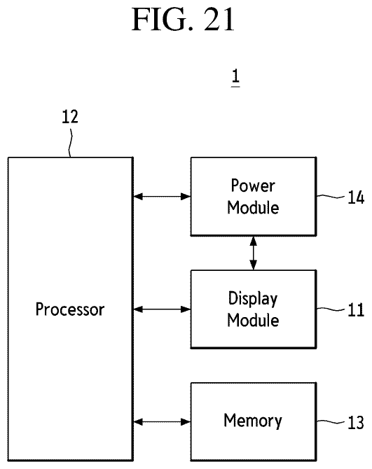

FIG. 21 is a block diagram of an electronic display device according to an embodiment.

Referring to FIG. 21 in addition to FIGS. 1 to 20, the display device 10 according to the embodiment may be applied to various electronic devices 1. The electronic device 1 according to an embodiment may include the display device 10 described herein, and may further include a module or device having additional functions in addition to the display device 10.

The electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

Data information for an operation of the processor 12 or the display module 11 may be stored in the memory 13. In an example in which the processor 12 executes an application stored in the memory 13, image data signals and/or input control signals may be transmitted to the display module 11, and the display module 11 may process the provided signals and output image information through a display screen.

The power module 14 may include a power supply module, such as, for example, a power adapter or a battery device, and a power conversion module that converts power supplied by the power supply module to generate power required for an operation of the electronic device 1.

At least one of the components of the electronic device 1 described herein may be included in the display device according to the embodiments described herein. In some aspects, some of the individual modules functionally included within one module may be included within the display device, while others may be provided separately from the display device. For example, the display device includes the display module 11, and the processor 12, the memory 13, and the power module 14 may be provided in the form of other devices within the electronic device 1 other than the display device.

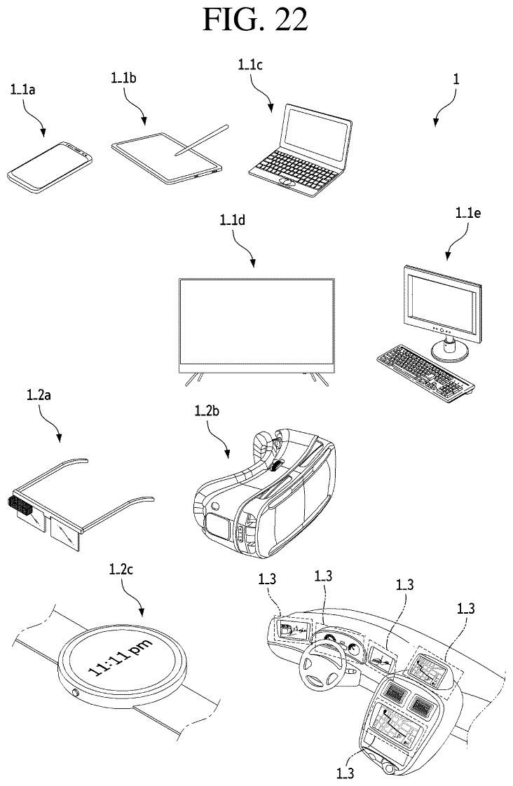

FIG. 22 illustrates schematic diagrams of electronic devices according to various embodiments.

Referring to FIG. 22 in addition to FIGS. 1 to 21, various electronic devices 1 to which the display device 10 according to the embodiments is applied may include not only an image display electronic device such as, for example, a smart phone 1_1a, a tablet PC 1_1b, a laptop 1_1c, a TV 1_1d, and a desk monitor 1_1e, but also a wearable electronic device including a display module such as, for example, a smart glasses 1_2a, a head mounted display 1_2b, a smart watch 1_2c, and the like, and a vehicle electronic device 1_3 including a display module such as, for example, a Center Information Display (CID), a room mirror display, or the like arranged on a vehicle's instrument panel, center fascia, or dashboard.

Those skilled in the art will appreciate that the present disclosure may be implemented in other specific forms without changing the technical spirit or essential characteristics thereof. Therefore, it should be understood that the embodiments described herein are in all respects and not limiting. The scope of the present specification is indicated by the scope of the claims described herein rather than the detailed description above, and all changes or modifications derived from the meaning and scope of the claims and their equivalent concepts should be interpreted as being included in the scope of the present specification.

However, the effects of the present disclosure are not restricted to the one set forth herein. The above and other effects of the present disclosure will become more apparent to one of daily skill in the art to which the present disclosure pertains by referencing the claims.

The invention should not be construed as being limited to the embodiments set forth herein. Rather, the example embodiments are provided such that this disclosure will be thorough and complete and will fully convey the concept of the invention to those skilled in the art.

While the invention has been particularly illustrated and described with reference to embodiments thereof, it will be understood by those of ordinary skill in the art that various changes in form and details may be made therein without departing from the spirit or scope of the invention as defined by the following claims.

What is claimed is:

1. A display device comprising:
a substrate comprising a light emitting area;
an anode electrode positioned on the light emitting area of the substrate and comprising silver; and
an element insulating layer covering an edge of the anode electrode and defining a light emitting opening,
wherein the anode electrode comprises:
a first layer positioned on the substrate;
a second layer positioned on the first layer; and
a third layer positioned on the second layer and comprising a protruding portion that protrudes further compared to a side surface of the second layer, and
a width of the protruding portion of the third layer is 0.1 micrometers or less.

2. The display device of claim 1, wherein:
the first layer comprises an upper surface,
the upper surface of the first layer comprises a first portion that is not in contact with the second layer and a second portion that is in contact with the second layer, and
a width of the first portion is 0.1 micrometers or less.

3. The display device of claim 2, wherein a thickness of the second layer is greater than a thickness of the first layer and a thickness of the third layer.

4. The display device of claim 3, wherein the first layer and the third layer each comprise a transparent conductive material.

5. The display device of claim 1, wherein:
the light emitting area comprises a first light emitting area and a second light emitting area adjacent to each other, and
the display device further comprises:
a first resonant auxiliary layer overlapping the first light emitting area and positioned between the first layer of the anode electrode and the substrate; and
a second resonant auxiliary layer overlapping the second light emitting area and spaced apart from the first resonant auxiliary layer,
wherein a thickness of the first resonant auxiliary layer and a thickness of the second resonant auxiliary layer are different from each other.

6. The display device of claim 5, wherein:
the display device comprises the anode electrode in plurality,
a first anode electrode of the plurality of anode electrodes is positioned on the first resonant auxiliary layer,
a second anode electrode of the plurality of anode electrodes is positioned on the second resonant auxiliary layer, and
the first anode electrode and the second anode electrode are positioned at different heights.

7. The display device of claim 5, wherein:
the display device comprises the anode electrode in plurality,
a first anode electrode of the plurality of anode electrodes overlaps the first light emitting area,
a second anode electrode of the plurality of anode electrodes overlaps the second light emitting area, and
a gap between the second layer of the first anode electrode overlapping the first light emitting area and a gap between the second layer of the second anode electrode overlapping the second light emitting area are each 1.86 micrometers or less.

8. The display device of claim 1, further comprising a residual pattern positioned in contact with the third layer of the anode electrode and positioned such that the residual pattern surrounds the light emitting opening,
wherein the residual pattern overlaps the protruding portion comprised in the third layer of the anode electrode.

9. A method for fabricating a display device, the method comprising:
forming a first layer, a second layer, and a third layer of an anode electrode on an entire surface;
removing a portion of the third layer by performing a dry etching process;
performing plasma treatment on a portion of the second layer;
performing a cleaning process after the plasma treatment; and
removing a portion of the first layer by performing a dry etching process.

10. The method of claim 9, wherein:
the first layer and the third layer each comprise a transparent conductive material, and
the second layer comprises silver.

11. The method of claim 10, wherein the plasma treatment:
is performed using a gas comprising fluorine, and
uses a bias power of 0 W among process parameter values of the plasma treatment.

12. The method of claim 11, wherein:
the plasma treatment further comprises oxygen gas, and
a portion of the second layer comprises silver fluoride.

13. The method of claim 12, wherein performing the cleaning process comprises dissolving the silver fluoride using at least one of organic stripper or deionized water.

14. The method of claim 9, wherein:
the third layer comprises a protruding portion that protrudes further compared to a side surface of the second layer, and
a width of the protruding portion is 0.1 micrometers or less.

15. The method of claim 9, wherein a side surface of the first layer, a side surface of the second layer, and a side surface of the third layer are positioned on the same line.

16. An electronic device comprising:
at least one display device comprising a substrate comprising a light emitting area; and
a display module, a processor, a memory, and a power module, wherein at least one of the display module, the processor, the memory, or the power module is connected to the at least one display device,
wherein:
the at least one display device further comprises:
an anode electrode positioned on the light emitting area of the substrate and comprising silver; and
an element insulating layer covering an edge of the anode electrode and defining a light emitting opening, and
the anode electrode comprises:
a first layer positioned on the substrate;
a second layer positioned on the first layer; and
a third layer positioned on the second layer and comprising a protruding portion that protrudes further compared to a side surface of the second layer,
wherein a width of the protruding portion of the third layer is 0.1 micrometers or less.

17. The electronic device of claim 16, wherein:
the first layer comprises an upper surface,
the upper surface of the first layer comprises a first portion that is not in contact with the second layer and a second portion that is in contact with the second layer, and
a width of the first portion is 0.1 micrometers or less.

18. The electronic device of claim 17, wherein a thickness of the second layer is greater than a thickness of the first layer and a thickness of the third layer.

19. The electronic device of claim 18, wherein the first layer and the third layer each comprise a transparent conductive material.

20. The electronic device of claim 16, wherein:
the light emitting area comprises a first light emitting area and a second light emitting area adjacent to each other,
the at least one display device comprises the anode electrode in plurality,
a first anode electrode of the plurality of anode electrodes overlaps the first light emitting area,
a second anode electrode of the plurality of anode electrodes overlaps the second light emitting area, and
a gap between the second layer of the first anode electrode overlapping the first light emitting area and a gap between the second layer of the second anode electrode overlapping the second light emitting area are each 1.86 micrometers or less.
